(19) United States
(12) Patent Application Publication
(10) Pub. No.: US 2024/0159816 A1
(43) Pub. Date: May 16, 2024

(54) DEVICE AND METHOD FOR APPLYING AND MEASURING A TRANSIENT OVERVOLTAGE IN AN ELECTRICAL CABLE

(71) Applicant: NEXANS, Courbevoie (FR)

(72) Inventors: Raphaël GUFFOND, LYON (FR); Patrick FORNAGE, Courbevoie (FR)

(21) Appl. No.: 18/384,951

(22) Filed: Oct. 30, 2023

(30) Foreign Application Priority Data
Nov. 2, 2022 (FR) 2211411

(51) Int. Cl. G01R 31/14

(52) U.S. Cl. CPC G01R 31/14

(57) ABSTRACT

A device (10) for applying and measuring a transient overvoltage in an electrical cable includes a test specimen representative of the electrical cable, a first DC voltage generator (DC₁) designed to apply a predetermined DC voltage to the specimen, and a second DC voltage generator (DC₂) designed to apply a predetermined overvoltage to the specimen. The device also has a high-voltage switch (12) that is connected to the second DC voltage generator (DC₂) and is designed to convert the predetermined overvoltage into a square-wave voltage, a control resistor (R2) designed to monitor the voltage rise time of the specimen, and a decoupling capacitor (C1) designed to monitor the overvoltage fall time in the specimen.

### RELATED APPLICATION

This application claims the benefit of priority from French Patent Application No. 22 11411, filed on Nov. 2, 2022, the entirety of which is incorporated by reference.

### FIELD OF THE INVENTION

The present invention relates to a device and to a method for applying and measuring a transient overvoltage in an electrical cable.

The invention belongs to the field of electrical cables intended to transport energy and/or to transmit data. It is particularly applicable to the field of analysing the behaviour of the electrical insulation of high-voltage direct current cables in the event of transient overvoltage (TOV).

### DESCRIPTION OF RELATED ART

In the field of HVDC (high-voltage direct current) cables, validation tests are required not only under DC power, but also to check the behaviour of the electrical insulation system of the cable in the event of unconventional waveforms occurring, such as temporary overvoltages with a very slow rising edge.

Currently, these validation tests are generally carried out on real insulation systems and on real cables. The process takes time and is expensive.

It is necessary to be able to carry out these tests in the laboratory on insulating plate specimens and/or cables of reduced dimension that are representative of real insulation systems and cables in order to study, more rapidly and at low cost, the electrical properties of the insulation system when it is subjected to an uncommon waveform of this kind.

### OBJECTS AND SUMMARY

The present invention aims to rectify the abovementioned drawbacks of the prior art.

For this purpose, the present invention proposes a device for applying and measuring a transient overvoltage in an electrical cable, comprising:
a first DC voltage generator designed to generate a predetermined DC voltage; and
a second DC voltage generator designed to generate a predetermined overvoltage,
the device being noteworthy in that it also comprises:
a test specimen representative of the electrical cable;
in that the first DC voltage generator is designed to apply the predetermined DC voltage to the test specimen;
in that the second DC voltage generator is designed to apply the predetermined overvoltage to the test specimen;
and in that it also comprises:
a high-voltage switch that is connected to the second DC voltage generator and is designed to convert the predetermined overvoltage into a square-wave voltage;
a control resistor designed to monitor the voltage rise time of the test specimen; and
a decoupling capacitor designed to monitor the overvoltage fall time in the test specimen.

Therefore, by virtue of a simple and inexpensive electrical circuit, the present invention makes it possible to perform validation tests in the laboratory on insulation system specimens and/or on mini-cables more rapidly and more economically than in the field.

In one particular embodiment, the device also comprises at least one protective resistor.

This makes it possible not to damage the test specimen while studying its behaviour upon the occurrence of the overvoltage.

In one particular embodiment, the high-voltage switch comprises at least one high-voltage fast transistor.

This makes it possible to quickly create an overvoltage and, in combination with the control resistor and the decoupling capacitor, to easily adjust the characteristics of the waveform associated with the overvoltage for the purposes of the validation test of the specimen.

In one particular embodiment, the test specimen is an electrically insulating plate having a thickness between 500 μm and 1.5 mm.

This makes it possible to reconstruct, at low cost, and on the small scale of the test laboratory, the electrical properties of an insulation system that are equivalent to those of a real electrical insulation system of a cable.

As a variant, the test specimen is a high-voltage direct current mini-cable having an insulation with a thickness of 1.5 mm.

This thickness of 1.5 mm should be compared with a thickness of 20 mm of insulation for a real cable, which shows the saving made by using a specimen and not a real cable.

For the same purpose as that indicated above, the present invention also proposes a method for measuring a transient overvoltage in an electrical cable by way of a device, as described succinctly above, noteworthy in that it comprises steps of:
applying the predetermined DC voltage to the test specimen by way of the first DC voltage generator;
applying the predetermined overvoltage, in the form of the square-wave voltage, to the test specimen by way of the second DC voltage generator and the high-voltage switch;
monitoring the voltage rise time by way of the control resistor;
monitoring the overvoltage fall time by way of the decoupling capacitor.

In one particular embodiment, the overvoltage is equal to 0.7 U₀, where U₀ denotes the predetermined DC voltage.

Since the particular features and the advantages of the method are similar to those of the device, they are not repeated here.

### BRIEF DESCRIPTION OF THE DRAWINGS

Other aspects and advantages of the invention will become apparent on reading the detailed description below of particular embodiments, which are given by way of entirely non-limiting examples, with reference to the appended drawings, in which:

FIG. 1 is a schematic representation of a device according to the present invention, in a particular embodiment.

FIG. 2 is a graph showing the level of overvoltage as a function of time in a test specimen comprised by a device according to the present invention, in a particular embodiment.

### DESCRIPTION OF EMBODIMENT(S)

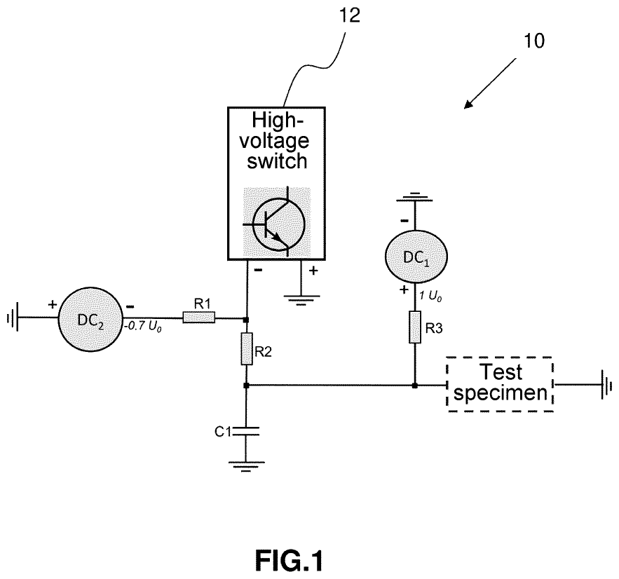

The circuit diagram in FIG. 1 shows a device 10, according to the present invention, for measuring a transient overvoltage in an electrical cable, in a particular embodiment. The invention applies in particular, but not solely, to HVDC cables subjected to voltages that may reach 800 kV.

The device 10 comprises a test specimen, which is illustrated by dashes in the drawing and representative of the electrical cable.

By way of non-limiting example, this test specimen may be an electrically insulating plate having a thickness between 500 μm and 1.5 mm, or else a high-voltage direct current mini-cable having an insulation with a length of 1.5 mm.

The device 10 also comprises a first DC voltage generator DCS designed to generate a predetermined DC voltage U₀. One terminal of the first DC voltage generator DCS is connected to earth and the other terminal thereof is connected to the test specimen, which is, moreover, also connected to earth. The first DC voltage generator DCS is therefore designed to apply the voltage U₀ to the test specimen.

The device 10 also comprises a second DC voltage generator DC₂ designed to generate a predetermined overvoltage. In the particular embodiment of FIG. 1, this overvoltage is 0.7 U₀. One terminal of the second DC voltage generator DC₂ is connected to earth and the other terminal thereof is connected to the test specimen. The second DC voltage generator DC₂ is therefore designed to apply the overvoltage 0.7 U₀ to the test specimen.

In order for the overvoltage to be applied only temporarily, the device 10 also comprises a high-voltage switch 12. One terminal of the high-voltage switch 12 is connected to earth and the other terminal thereof is connected to the second DC voltage generator DC₂. The high-voltage switch 12 is designed to convert the overvoltage into a voltage, the waveform of which is a square wave, with a view to applying it to the test specimen.

By way of entirely non-limiting example, the high-voltage switch 12 can be closed for 130 ms, that is to say that, during this time interval, the + and − terminals of the high-voltage switch 12 are connected to one another. The overvoltage 0.7 U₀ is then applied to the test specimen for 130 ms.

By way of entirely non-limiting example, the high-voltage switch 12 can comprise at least one high-voltage fast transistor. In the particular embodiment shown, the high-voltage switch 12 is a high-voltage fast transistor.

In order to monitor the voltage rise time of the test specimen when the overvoltage is applied thereto, that is to say to measure this voltage rise time, the device 10 also comprises a control resistor R2, of which one terminal is connected to the second DC voltage generator DC₂ and to the high-voltage switch 12 and the other terminal is connected to the test specimen and to earth.

Moreover, in order to monitor the overvoltage fall time in the test specimen, that is to say to measure this time when the overvoltage is no longer applied, the device 10 also comprises a decoupling capacitor C1, of which one terminal is connected to the second DC voltage generator DC₂ and to the high-voltage switch 12 and the other terminal is connected to the test specimen and to earth.

Optionally, the device 10 can also comprise one or more protective resistors. In the particular embodiment shown, the device 10 comprises a first protective resistor R1 connected between the second DC voltage generator DC₂ and the high-voltage switch 12 and a second protective resistor R3, of which one terminal is connected to the first DC voltage generator DCS and the other terminal is connected between, on the one hand, the test specimen and, on the other hand, the second DC voltage generator DC₂ and the high-voltage switch 12.

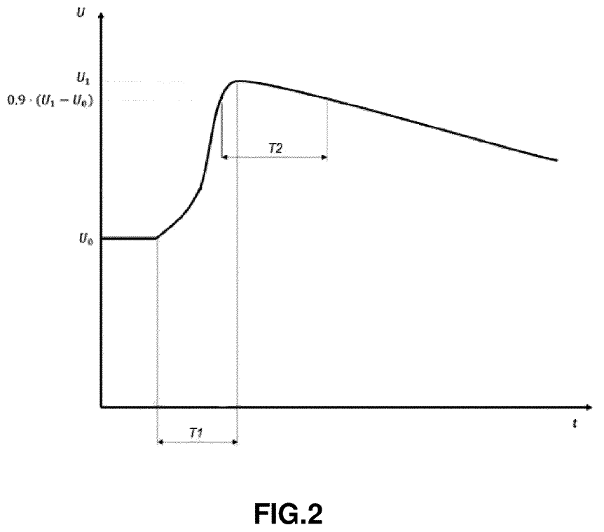

The graph in FIG. 2 shows the evolution of the voltage U and therefore the level of overvoltage as a function of time t.

The voltage at the start of the test is U₀. Then, when the overvoltage 0.7 U₀ is applied to the test specimen, the voltage reaches a peak U₁, the value of which therefore being 1.7 U₀.

The control resistor R2 makes it possible to measure the time interval T1 between the start of the voltage rise and the voltage peak U₁. Typically, it is found that T1 is between 1 and 3 ms.

The decoupling capacitor C1 makes it possible to measure the time interval T2 during which the voltage exceeds 90% of its maximum value (namely 0.9. (U₁-U₀), as shown on the graph). Typically, it is found that T2 is between 10 and 150 ms.

Therefore, the method, according to the present invention, for measuring a transient overvoltage of an electrical cable by way of the device 10 comprises the following steps.

The first DC voltage generator DCS applies the predetermined DC voltage U₀ to the test specimen.

Then, the second DC voltage generator DC₂ applies the predetermined overvoltage, 0.7 U₀ in the non-limiting example given here, in the form of a square wave provided by the high-voltage switch 12, to the test specimen.

The control resistor R2 then monitors, i.e. measures, the voltage rise time T1 of the test specimen and the decoupling capacitor C1 monitors, i.e. measures, the overvoltage fall time T2.

Therefore, the device 10 and the method according to the invention make it possible to monitor the waveform associated with the applied overvoltage, in particular the voltage rise time T1 and the overvoltage fall time T2, precisely, rapidly and at low cost.

1. A device for applying and measuring a transient overvoltage in an electrical cable, comprising:
a first DC voltage generator designed to generate a predetermined DC voltage; and
a second DC voltage generator designed to generate a predetermined overvoltage,
wherein said device further comprises:
a test specimen representative of said electrical cable;
in that said first DC voltage generator is designed to apply said predetermined DC voltage to said test specimen;
in that said second DC voltage generator is designed to apply said predetermined overvoltage to said test specimen;
and in that the device also comprises:
a high-voltage switch that is connected to said second DC voltage generator and is designed to convert said predetermined overvoltage into a square-wave voltage;
a control resistor designed to monitor the voltage rise time of said test specimen; and
a decoupling capacitor designed to monitor the overvoltage fall time in said test specimen.

2. The device according to claim 1, wherein said device further comprises at least one protective resistor.

3. The device according to claim 1, wherein said high-voltage switch comprises at least one high-voltage fast transistor.

4. The device according to claim 1, wherein said test specimen is an electrically insulating plate having a thickness between 500 μm and 1.5 mm.

5. The device according to claim 1, wherein said test specimen is a high-voltage direct current mini-cable having an insulation with a thickness of 1.5 mm.

6. A method for applying and measuring a transient overvoltage in an electrical cable by way of a device according to claim 1, wherein said method comprises steps of:
applying said predetermined DC voltage to said test specimen by way of said first DC voltage generator;
applying said predetermined overvoltage, in the form of said square-wave voltage, to said test specimen by way of said second DC voltage generator and said high-voltage switch;
monitoring said voltage rise time by way of said control resistor; and
monitoring said overvoltage fall time by way of said decoupling capacitor.

7. The method according to claim 6, wherein said overvoltage is equal to 0.7 U₀, where U₀ denotes said predetermined DC voltage.
